(19) United States
(12) Patent Application Publication
(10) Pub. No.: US 2025/0231488 A1
(43) Pub. Date: Jul. 17, 2025

(54) ANTI-REFLECTIVE COATING COMPOSITION

(71) Applicant: TAN KAH KEE INNOVATION LABORATORY, Xiamen (CN)

(72) Inventors: Aiqiang Zhang, Xiamen (CN); Renzhi Chen, Xiamen (CN); Yuan Chen, Xiamen (CN); Yimin Jiang, Xiamen (CN)

(21) Appl. No.: 19/057,555

(22) Filed: Feb. 19, 2025

Related U.S. Application Data
(63) Continuation of application No. PCT/CN2022/118638, filed on Sep. 14, 2022.

(30) Foreign Application Priority Data
Aug. 19, 2022 (CN) 202211003458.3

(51) Int. Cl. G03F 7/11; C08F 212/14; C08F 220/14; C08F 220/30; C08F 220/58; C09D 5/00; C09D 125/18; C09D 133/06; C09D 133/14; C09D 133/26; G03F 7/16

(52) U.S. Cl. CPC G03F 7/11; C08F 212/24; C08F 220/14; C08F 220/301; C08F 220/58; C09D 5/006; C09D 125/18; C09D 133/066; C09D 133/14; C09D 133/26; C08F 2810/20; G03F 7/16

(57) ABSTRACT

The present disclosure provides an anti-reflective coating composition comprising an organic polymer; the organic polymer comprises a crosslinkable polymer; the crosslinkable polymer comprises a monomer unit formed by a monomer represented by formula (I). As compared with the prior art, the crosslinkable polymer provided by the present disclosure comprises hydroxyl group can be crosslinked with a crosslinking agent containing amino group and/or alkoxyl-substituted amino group at a relatively low baking temperature, so that the baking temperature of the anti-reflective coating composition is reduced. The outgassing during its baking process can be effectively solved or reduced. By doing so, unnecessary cleaning processes are reduced while the patterns damage due to falling of solid particles formed by gas condensation is significantly reduced. Therefore, the overall process flow can be simplified and the relevant cost could be reduced effectively.

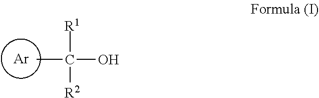

### CROSS-REFERENCE TO RELATED APPLICATIONS

The present application is a Continuation of International Patent Application No. PCT/CN2022/118638, filed on Sep. 14, 2022, which claims the benefit of and priority to Chinese Application No. 202211003458.3, filed Aug. 19, 2022, which are both incorporated herein by reference in their entirety.

### TECHNICAL FIELD

The present disclosure belongs to the technical field of semiconductors, and especially, it relates to an anti-reflective coating composition.

### BACKGROUND

In particular, the photolithographic process, by utilizing the photosensitive function of a photoresist, transfers a fine circuit pattern from mask to photoresist and then to silicon wafer substrate eventually, to make preparations for subsequent etching or ion implantation.

However, as the more and more highly integrated semiconductor devices is developed, a shorter incident light wavelength from i-line (365 nm) to deep ultraviolet-line (248 nm and 193 nm) is required to meet higher and higher resolution requirement of IC chip during exposure process. The shorter and shorter wavelength tendency of incident light induces the more and more severe light diffusion reflection from substrates and standing waves, etc., which will seriously cause image distortion and poor resolution etc. issues.

To overcome the above problems, an effective solution is to introduce an anti-reflective coating layer between the photoresist and the substrate to reduce and even eliminate reflections from the substrate. The anti-reflective coating layer mainly includes the following two types: an inorganic coating layer and an organic coating layer comprising a light-absorbing component and a polymer. Among them, the inorganic anti-reflective coating layer has the following drawbacks: required special equipment, more process steps, subsequent difficulties to rework. While as organic anti-reflective coating layer, similar to photoresist, can be coated by spin-on process, which will effectively simplify overall process flow and reduce costs Therefore, it is widely applied and studied.

After the organic anti-reflective coating process, a high-temperature baking is applied to further crosslink and cure it. During the baking process, “outgassing” from some of its chemical components occurs, which causes great problem. Typically, the “outgassing” mainly comes from small molecular compounds such as crosslinking agent etc., and the equipment exhaust system cannot completely remove them. The outgassing species condense on the inner chamber wall of baking equipment. Such condensates could fall off onto subsequent wafers, leading to cross contamination.

### SUMMARY

The present disclosure is to provide an anti-reflective coating composition, which can effectively eliminate or reduce the “outgassing” during baking process.

The present disclosure provides an anti-reflective coating composition, comprising an organic polymer;
the organic polymer comprises a crosslinkable polymer;
the crosslinkable polymer comprises a monomer unit formed by a monomer represented by formula (I):

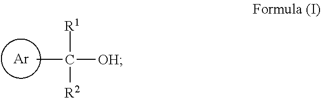

wherein

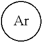

is selected from substituted C₆-C₂₀ aryl or substituted C₃-C₂₀ heteroaryl;
the substituents in the substituted C₆-C₂₀ aryl and substituted C₃-C₂₀ heteroaryl include unsaturated bonds;
the R¹ and R² are each independently selected from a group consisting of H, substituted or unsubstituted C₁-C₆ alkyl, and substituted or unsubstituted C₆-C₂₀ aryl.

Preferably, the substituents in the substituted C₆-C₂₀ aryl and substituted C₃-C₂₀ heteroaryl are selected from a group consisting of substituted or unsubstituted C₄-C₁₅ alkenoic alkyl ester group, and substituted or unsubstituted C₂-C₁₀ alkenyl;
the substituents in the substituted C₄-C₁₅ alkenoic alkyl ester group and substituted C₂-C₁₀ alkenyl are each independently one or more selected from a group consisting of C₁-C₅ alkyl, C₁-C₆ alkoxy and phenyl;
the substituents in the substituted C₁-C₆ alkyl and substituted C₆-C₂₀ aryl are each independently one or more selected from a group consisting of C₁-C₅ alkyl, C₁-C₆ alkoxy and phenyl.

Preferably,

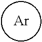

is selected from substituted phenyl, substituted naphthyl, substituted anthryl, substituted pyridyl or substituted furyl.

Preferably, the monomer represented by formula (I) is one or more selected from a group consisting of (4-hydroxymethyl)benzyl methacrylate, 4-hydroxymethyl styrene, (4-hydroxymethyl)pyridylmethyl methacrylate, (4-hydroxymethyl) furylmethyl methacrylate, (8-hydroxymethyl) 1-anthrylmethyl methacrylate and (6-hydroxymethyl) 1-naphthylmethyl methacrylate.

Preferably, the amount of the monomer unit formed by the monomer represented by formula (I) in the crosslinkable polymer is 5-60 wt %; the mass of the crosslinkable polymer is 10%-100% of the mass of the organic polymer; the mass of the organic polymer is 2%-10% of the mass of the anti-reflective coating composition.

Preferably, the crosslinkable polymer further comprises a light-absorbing organic chromophore and/or the organic polymer further comprises a first polymer; the first polymer comprises a light-absorbing organic chromophore; the light-absorbing organic chromophore is one or more selected from a group consisting of substituted or unsubstituted aryl, polyhaloalkyl, and a substituted or unsubstituted isocyanuric acid ester group.

Preferably, the mass of the monomer unit comprising the light-absorbing organic chromophore is 10%-85% of the mass of the organic polymer.

Preferably, the anti-reflective coating composition further comprises a crosslinking agent; the crosslinking agent is one or more selected from a group consisting of a melamine crosslinking agent, a urea crosslinking agent, and an epoxy group-containing polymeric crosslinking agent; the mass of the crosslinking agent is 0.1%-20% of the mass of the anti-reflective coating composition.

Preferably, the melamine crosslinking agent is one or more selected from a group consisting of methoxymethylated melamine, melamine, benzoguanamine and the corresponding resins of the above materials.

The urea crosslinking agent is one or more selected from a group consisting of methoxymethylated glycoluril, tetramethoxymethyl urea and tetrabutoxymethyl urea.

Preferably, the anti-reflective coating composition further comprises a thermal acid generator, a photoacid generator, a surfactant and a solvent; the mass of the thermal acid generator is 0.1%-15% of the mass of the anti-reflective coating composition; the mass of the photoacid generator is 0%-15% of the mass of the anti-reflective coating composition; the mass of the surfactant is 0%-20% of the mass of the anti-reflective coating composition; the mass of the solvent is 90%-99% of the mass of the anti-reflective coating composition.

The present disclosure also provides a method for forming a pattern image with photoresist during manufacturing semiconductor device, comprising: a film-forming step of the above anti-reflective coating composition, a film-forming step of photoresist, and a subsequent irradiation-exposing step followed by the developing step of photoresist.

The present disclosure provides an anti-reflective coating composition comprising an organic polymer; the organic polymer comprises a crosslinkable polymer; the crosslinkable polymer comprises a monomer unit formed by a monomer represented by formula (I). As compared with the prior art, the crosslinkable polymer provided by the present disclosure comprises hydroxyl group can be crosslinked with a crosslinking agent containing amino group and/or alkoxyl-substituted amino group at a relatively low baking temperature, so that the baking temperature of the anti-reflective coating composition is reduced. The outgassing during its baking process can be effectively solved or reduced. By doing so, unnecessary cleaning processes are reduced while the patterns damage due to falling of solid particles formed by gas condensation is significantly reduced. Therefore, the overall process flow can be simplified and the relevant cost could be reduced effectively.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a Hydrogen Nuclear Magnetic Resonance (1H-NMR) spectrogram of the polymer obtained in Example 2 of the present disclosure;

FIG. 2 is a 1H-NMR spectrogram of the polymer obtained in Example 3 of the present disclosure;

FIG. 3 is a 1H-NMR spectrogram of the polymer obtained in Example 4 of the present disclosure;

FIG. 4 is a 1H-NMR spectrogram of the polymer obtained in Example 5 of the present disclosure;

FIG. 5 is a 1H-NMR spectrogram of the polymer obtained in Example 6 of the present disclosure;

FIG. 6 is a 1H-NMR spectrogram of the polymer obtained in Example 7 of the present disclosure;

FIG. 7 is a 1H-NMR spectrogram of the polymer obtained in Example 8 of the present disclosure;

FIG. 8 is a 1H-NMR spectrogram of the polymer obtained in Example 9 of the present disclosure;

FIG. 9 is a 1H-NMR spectrogram of the polymer obtained in Example 10 of the present disclosure;

FIG. 10 is a structural diagram of the structure of the apparatus used in the examples of the present disclosure for evaluating the outgassing effect; and

FIG. 11 is a diagram showing the results of outgassing evaluations for the anti-reflective coating compositions obtained in the examples and comparative examples of the present disclosure.

### DETAILED DESCRIPTION

The following contents, with reference to the examples of the present disclosure, clearly and completely describe the technical solutions in the examples of the present disclosure, and obviously, the described examples are only a part of the examples of the present disclosure, but not all the examples. Based on the examples in the present disclosure, all other examples acquired by those skilled in the art, under the premise of not making any creative efforts, belong to the protection scope of the present disclosure.

The present disclosure provides an anti-reflective coating composition comprising an organic polymer; the organic polymer comprises a crosslinkable polymer; the crosslinkable polymer comprises a monomer unit formed by a monomer represented by formula (I):

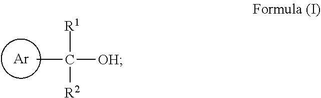

wherein

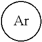

is substituted C₆-C₂₀ aryl or substituted C₃-C₂₀ heteroaryl, preferably substituted C₆-C₁₅ aryl or substituted C₃-C₁₅ heteroaryl, more preferably substituted C₆-C₁₂ aryl or substituted C₃-C₁₂ heteroaryl, and further preferably substituted C₆-C₁₁ aryl or substituted C₃-C₁₁ heteroaryl; the heteroatoms in the heteroaryl are one or more selected from a group consisting of S, O and N;
in the present disclosure, most preferably, the

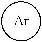

is substituted phenyl, substituted naphthyl, substituted anthryl, substituted pyridyl or substituted furyl.

The hydroxyl group of the monomer unit forming the crosslinkable polymer in the present disclosure is connected to the carbon atom directly connected to the aryl or heterocyclic group, which can significantly reduce the amount of the outgassing release during the baking process. And the present disclosure uses a hydroxyl-containing crosslinkable polymer capable of sufficiently crosslinking with a crosslinking agent containing amino group and/or alkoxyl-substituted amino group at a relative low baking temperature, so that the baking temperature of the anti-reflective coating composition is reduced. Gas generation of a composition during its baking process can be effectively solved or reduced. By doing so, unnecessary cleaning processes are reduced while the patterns damage due to falling of solids formed by gas condensation is significantly reduced. Therefore, the overall process flow can be simplified, the relevant cost could be reduced effectively, and the rate of qualified products and the yield are increased.

In some embodiments, the substituents in the substituted C₆-C₂₀ aryl and substituted C₃-C₂₀ heteroaryl include unsaturated bonds; the number of the unsaturated bonds may be one or more, and in the present disclosure, it is preferably 1-2, more preferably 1; further preferably, the substituents in the substituted C₆-C₂₀ aryl and substituted C₃-C₂₀ heteroaryl are substituted or unsubstituted C₄-C₁₅ alkenoic alkyl ester group, and substituted or unsubstituted C₂-C₁₀ alkenyl, more preferably substituted or unsubstituted C₄-C₁₀ alkenoic alkyl ester group, and substituted or unsubstituted C₂-C₈ alkenyl, even more preferably substituted or unsubstituted C₅-C₈ alkenoic alkyl ester group, and substituted or unsubstituted C₂-C₆ alkenyl, further preferably substituted or unsubstituted C₅-C₆ alkenoic alkyl ester group, and substituted or unsubstituted C₂-C₄ alkenyl, and most preferably substituted or unsubstituted C₅-C₆ alkenoic alkyl ester group, and substituted or unsubstituted C₂-C₃ alkenyl; the substituents in the substituted or unsubstituted C₄-C₁₅ alkenoic alkyl ester group and substituted or unsubstituted C₂-C₁₀ alkenyl are each independently one or more selected from a group consisting of C₁-C₅ alkyl, C₁-C₆ alkoxy and phenyl, more preferably one or more of C₁-C₃ alkyl, C₁-C₄ alkoxy and phenyl, and further preferably one or more of C₁-C₂ alkyl, C₁-C₂ alkoxy and phenyl.

In some embodiments, the R¹ and R² are each independently H, substituted or unsubstituted C₁-C₆ alkyl, and substituted or unsubstituted C₆-C₂₀ aryl, preferably H, substituted or unsubstituted C₁-C₆ alkyl, and substituted or unsubstituted C₆-C₁₅ aryl, more preferably H, substituted or unsubstituted C₁-C₄ alkyl, and substituted or unsubstituted C₆-C₁₀ aryl, and further preferably H, substituted or unsubstituted C₁-C₂ alkyl, and substituted or unsubstituted phenyl; the substituents in the substituted or unsubstituted C₁-C₆ alkyl and substituted or unsubstituted C₆-C₂₀ aryl are each independently one or more selected from a group consisting of C₁-C₈alkyl, C₁-C₆ alkoxy and phenyl, more preferably one or more of C₁-C₃ alkyl, C₁-C₄ alkoxy and phenyl, and further preferably one or more of C₁-C₂ alkyl, C₁-C₂ alkoxy and phenyl.

In some embodiments of the present disclosure, most preferably, the monomer represented by formula (I) is one or more selected from a group consisting of (4-hydroxymethyl)benzyl methacrylate, 4-hydroxymethyl styrene, (4-hydroxymethyl)pyridylmethyl methacrylate, (4-hydroxymethyl) furylmethyl methacrylate, (8-hydroxymethyl) 1-anthrylmethyl methacrylate and (6-hydroxymethyl) 1-naphthylmethyl methacrylate.

In some embodiments of the present disclosure, the amount of the monomer unit formed by the monomer represented by formula (I) in the crosslinkable polymer is preferably 5 wt %-60 wt %, more preferably 5 wt %-50 wt %, further preferably 5 wt %-40 wt %, and most preferably 5 wt %-35 wt %; in the examples provided by the present disclosure, the amount of the monomer unit formed by the monomer represented by formula (I) in the crosslinkable polymer is specifically 23 wt %, 21 wt %, 9.5 wt %, 15.7 wt %, 27.7 wt % or 42 wt %.

The crosslinkable polymer, in addition to the monomer unit formed by the monomer represented by formula (I), preferably further comprises an acrylates monomer unit and/or an acrylamides monomer unit; the acrylates monomer for forming the acrylates monomer unit are not particularly limited as long as they are acrylic monomers well known to those skilled in the art, and in the present disclosure, they are preferably substituted or unsubstituted alkyl acrylates and substituted or unsubstituted alkyl methacrylates; the acrylamides monomer for forming the acrylamides monomer unit are not particularly limited as long as they are acrylamides monomers well known to those skilled in the art, and in the present disclosure, they are preferably substituted or unsubstituted acrylamides and substituted or unsubstituted methacrylamides; the number of carbon atoms in the alkyl groups of the substituted or unsubstituted alkyl acrylates and substituted or unsubstituted alkyl methacrylates is preferably 1-8, more preferably 1-6, and further preferably 1-4; the substituents in the substituted alkyl acrylates, substituted alkyl methacrylates, substituted acrylamides and substituted methacrylamides are each independently preferably one or more selected from a group consisting of hydroxyl, amino, sulfhydryl, halogen, C₁-C₅alkyl, C₁-C₅alkoxy, C₂-C₆ ether group and light-absorbing chromophore, more preferably one or more selected from a group consisting of hydroxyl, amino, sulfhydryl, halogen, C₁-C₄ alkyl, C₁-C₄ alkoxy, C₂-C₅ ether group and light-absorbing chromophore, further preferably one or more selected from a group consisting of hydroxyl, amino, sulfhydryl, halogen, C₁-C₃ alkyl, C₁-C₃ alkoxy, C₂-C₄ ether group and light-absorbing chromophore, and most preferably one or more selected from a group consisting of hydroxyl, amino, sulfhydryl, halogen, C₁-C₂ alkyl, C₁-C₂ alkoxy, C₂-C₃ ether group and light-absorbing chromophore; said halogen is preferably one or more selected from a group consisting of chlorine, bromine and iodine; the light-absorbing organic chromophore is preferably one or more selected from a group consisting of substituted or unsubstituted aryl, polyhaloalkyl, and a substituted or unsubstituted isocyanuric acid ester group; among them, the substituted or unsubstituted aryl, not being particularly limited, may be substituted or unsubstituted monocyclic aryl or substituted or unsubstituted polycyclic aryl, and in the present disclosure, it is preferably substituted or unsubstituted phenyl, substituted or unsubstituted naphthyl, substituted or unsubstituted anthryl, or substituted or unsubstituted quinolyl; the number of carbon atoms of the alkyl in the polyhaloalky is preferably 1-10, more preferably 1-8, further preferably 1-6, further preferably 1-4, and most preferably 1-2; the halogens in the polyhaloalkyl are preferably one or more selected from a group consisting of bromine and iodine; the number of the halogens in the polyhaloalkyl is preferably 2-4, and more preferably 3-4; the substituents in the substituted aryl and substituted isocyanuric acid ester group are each independently one or more selected from a group consisting of C₁-C₈ alkyl, C₆-C₁₀ aryl, hydroxyl, carbonyl and an ether group, more preferably one or more selected from a group consisting of C₁-C₅alkyl, C₆-C₈ aryl, hydroxyl, carbonyl and an ether group, and further preferably one or more selected from a group consisting of C₁-C₃ alkyl, C₆-C₈ aryl, hydroxyl, carbonyl and an ether group.

According to some embodiments of the present disclosure, further preferably, the acrylates monomer unit and/or the acrylamides monomer unit in the crosslinkable polymer at least comprise an acrylates monomer unit substituted by organic light-absorbing chromophore and/or an acrylamides monomer unit substituted by organic light-absorbing chromophore; the mass of the acrylates monomer unit substituted by an organic light-absorbing chromophore and/or the acrylamides monomer unit substituted by organic light-absorbing chromophore is preferably 5%-50%, more preferably 10%-40%, further preferably 10%-37%, and most preferably 12%-37%, of the mass of the crosslinkable polymer; in the examples provided by the present disclosure, the mass of the acrylates monomer unit substituted by an organic light-absorbing chromophore and/or the acrylamides monomer unit substituted by organic light-absorbing chromophore is specifically 26.4%, 15.8%, 24.3%, 12.3%, 37%, or 22.7% of the mass of the crosslinkable polymer.

To enable the anti-reflective coating composition to absorb non-essential active light back to the photoresist, the crosslinkable polymer of some embodiments further comprises an light-absorbing organic chromophore and/or the organic polymer further comprises a first polymer; the first polymer comprises a light-absorbing organic chromophore; that is, the organic polymer comprises a light-absorbing organic chromophore that may be grafted either to the crosslinkable polymer or to the first polymer, and alternatively, two of them comprise a light-absorbing organic chromophore, which are not particularly limited; the light-absorbing organic chromophore is not particularly limited as long as it is a light-absorbing organic chromophore well known to those skilled in the art, and the light-absorbing organic chromophore in some embodiments of the present disclosure is one or more selected from a group consisting of a substituted or unsubstituted aryl, polyhaloalkyl, and a substituted or unsubstituted isocyanuric acid ester group; among them, the substituted or unsubstituted aryl, not being particularly limited, may be substituted or unsubstituted monocyclic aryl or substituted or unsubstituted polycyclic aryl, and in some embodiments of the present disclosure, it is preferably substituted or unsubstituted phenyl, substituted or unsubstituted naphthyl, substituted or unsubstituted anthryl, or substituted or unsubstituted quinolyl; the number of carbon atoms of the alkyl in the polyhaloalky is preferably 1-10, more preferably 1-8, further preferably 1-6, even preferably 1-4, and most preferably 1-2; the halogens in the polyhaloalkyl are preferably one or more selected from a group consisting of fluorine, bromine and iodine; the number of the halogens in the polyhaloalkyl is preferably 2-4, and more preferably 3-4; the substituents in the substituted aryl and the substituted isocyanuric acid ester group are each independently one or more selected from a group consisting of C₁-C₈ alkyl, C₆-C₁₀ aryl, hydroxyl, carbonyl and an ether group. In some embodiments of the present disclosure, the used light-absorbing organic chromophore may vary according to different exposure rays, and for example, for a exposure ray with a wavelength of 248 nm, it is preferred that the light-absorbing organic chromophore is one or more of substituted or unsubstituted naphthyl and substituted or unsubstituted anthryl; for a exposure ray with a wavelength of 193 nm, it is preferred that the light-absorbing organic chromophore is one or more of substituted or unsubstituted naphthyl and substituted or unsubstituted phenyl. In some embodiments of the present disclosure, the mass of the monomer unit comprising light-absorbing chromophores is preferably 10%-85%, more preferably 15%-60%, and further preferably 20%-60%, of the mass of the organic polymer.

According to some embodiments of the present disclosure, the anti-reflective coating composition preferably further comprises a crosslinking agent; the crosslinking agent is preferably one or more selected from a group consisting of a melamine crosslinking agent, a urea crosslinking agent, and an epoxy group-containing polymeric crosslinking agent; the mass of the crosslinking agent is 0.1%-20% of the mass of the anti-reflective coating composition.

Further preferably, the melamine crosslinking agent is one or more selected from a group consisting of methoxymethylated melamine, melamine, benzoguanamine and the corresponding resins of the above materials; the urea crosslinking agent is one or more selected from a group consisting of methoxymethylated glycoluril, tetramethoxymethyl urea and tetrabutoxy methyl urea.

According to some embodiments of the present disclosure, the anti-reflective coating composition further comprises a thermal acid generator, a photoacid generator, a surfactant and a solvent.

Among them, the mass of the thermal acid generator is 0.01%-15%, preferably 0.01%-10%, more preferably 0.01%-5%, even more preferably 0.01%-2%, further preferably 0.01%-1%, and most preferably 0.05%-0.5%, of the mass of the anti-reflective coating composition; the thermal acid generator is preferably selected from a group consisting of an ionic thermal acid generator and/or a non-ionic thermal acid generator; the ionic thermal acid generator is preferably one or more selected from a group consisting of triethylamine dodecyl sulfonate, amine p-toluenesulfonate and sulfonate; the sulfonate are preferably one or more selected from a group consisting of carbocyclic aryl sulfonate, heteroaryl sulfonate, aliphatic sulfonate, benzenesulfonate and triflate; the non-ionic thermal acid generator is preferably one or more selected from a group consisting of cyclohexyl triflate, methyl triflate, cyclohexyl 2,4,6-triisopropylbenzenesulfonate, 2-nitrobenzyl p-toluenesulfonate, benzoin toluenesulfonate, 2-nitrobenzyl toluenesulfonate, tris(2,3-dibromopropyl)-1,3,5-triazine-trione, organic sulfonic acid alkyl ester, p-toluenesulfonic acid, dodecylbenzenesulfonic acid, oxalic acid, phthalic acid, phosphoric acid, camphorsulfonic acid and salts of the above materials, or those disclosed in U.S. Pat. No. 10,429,737B2.

The mass of the photoacid generator is preferably 0%-15%, more preferably 0.01%-10%, more preferably 0.01%-10%, even more preferably 0.01%-8%, further preferably 0.01%-5%, even further preferably 0.01%-2%, still preferably 0.01%-1%, and most preferably 0.01%-0.5%, of the mass of the anti-reflective coating composition; the photoacid generator is not particularly limited as long as it is a photoacid generator well known to those skilled in the art, and in some embodiments of the present disclosure, it is preferably one or more of onium salt photoacid generators, nitrobenzyl derivatives, sulfonate photoacid generators, diazomethane derivatives, glyoxime derivatives, sulfonate derivatives of N-hydroxyimide compounds, and halogen-containing triazine compounds, and more preferably one or more selected from a group consisting of iodonium (tetra-t-butylphenyl)-triflate, sulfonium triphenytriflate, triphenylsulfonium triflate, (p-tert-butoxyphenyl)diphenylsulfonium triflate, tris(p-t-butoxyphenyl) sulfonium triflate, triphenylsulfonium p-toluenesulfonate, 2-nitrobenzyl-p-toluenesulfonate, 2,6-dinitrobenzyl-p-toluenesulfonate, 2,4-dinitrobenzyl-p-toluenesulfonate, benzoin toluenesulfonate, N-hydroxysuccinimide triflate, 1,2,3-tris(methanesulfonyloxy)benzene, 1,2,3-tris(trifluoromethanesulfonyloxy)benzene, 1,2,3-tris(p-toluenesulfonyloxy)benzene, bis(benzenesulfonyl)azimethane, bis(p-toluenesulfonyl)azimethane, bis-O-(p-toluenesulfonyl)-α-dimethylglyoxime, bis-O-(n-butanesulfonyl)-α-dimethylglyoxime, N-hydroxysuccinimide methanesulfonate, N-hydroxysuccinimide triflate, phenylbis(trichloromethyl)-s-triazine, 2-(4-methoxyphenyl)-4,6-bis(trichloromethyl)-1,3,5-triazine and 2-(4-methoxynaphthyl)-4,6-bis(trichloromethyl)-1,3,5-triazine.

The mass of the surfactant is preferably 0%-20%, more preferably 0%-15% and further preferably 1%-10%, of the mass of the anti-reflective coating composition; the surfactant is preferably a nonionic surfactant, and more preferably one or more selected from a group consisting of polyoxyethylene lauryl(dodecyl) ether, polyoxyethylene stearyl ether, polyoxyethylene hexadecyl ether, polyoxyethylene oleyl ether, polyoxyethylene octylphenol ether, polyoxyethylene nonylphenol ether, polyoxyethylene-polyoxypropylene block copolymer, sorbitan monolaurate, sorbitan monopalmitate (hexadecanoate), sorbitan monostearate, sorbitan monooleate (octadec-9-enoate), sorbitan trioleate, sorbitan tristearate, polyoxyethylene sorbitan monolaurate, polyoxyethylene sorbitan monopalmitate (hexadecanoate), polyoxyethylene sorbitan monostearate, polyoxyethylene sorbitan monooleate octadec-9-enoate), polyoxyethylene sorbitan trioleate, and polyoxyethylene sorbitan tristearate.

The mass of the solvent is preferably 90%-99%, more preferably 95%-99%, and further preferably 95%-97%, of the mass of the anti-reflective coating composition; the solvent is not particularly limited as long as it is an organic solvent well known to those skilled in the art, and in some embodiments of the present disclosure, it is preferably one or more of alcohol, ester, ether and cyclic ketone solvents, and more preferably one or more selected from a group consisting of ethylene glycol monomethyl ether, ethylene glycol monoethyl ether, methylcellosolve acetate, ethylcellosolve acetate, diethylene glycol monomethyl ether, diethylene glycol diethyl ether, propylene glycol, propylene glycol monomethyl ether, propylene glycol monomethyl ether acetate, propylene glycol propyl ether acetate, toluene, xylene, methyl ethyl ketone, cyclopentanone, cyclohexanone, ethyl 2-hydroxypropionate, methyl 2-hydroxy-3-methylbutyrate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide (DMF), and N-methylpyrrolidone.

The present disclosure further provides the application of the above anti-reflective coating composition in a photolithographic process; the anti-reflective coating composition is disposed between the photoresist layer and the substrate to form an anti-reflective coating layer that can reduce reflections of exposure irradiations from the substrate to the photoresist; the thickness of the anti-reflective coating layer is preferably 10 nm-100 nm, and more preferably 33 nm-100 nm.

The present disclosure also provides a method for forming a pattern image with photoresist during manufacturing semiconductor device, comprising a film-forming step of the above anti-reflective coating composition, a film-forming step of the photoresist, and a subsequent irradiation-exposing step followed by the developing step of photoresist.

To further illustrate the present disclosure, the following examples are combined to describe in detail the anti-reflective coating composition and crosslinkable polymer provided by the present disclosure.

All reagents used in the following examples are commercially available.

### Example 1

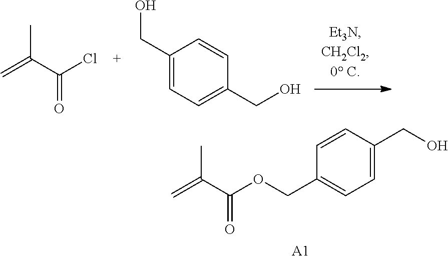

Taking A1 ((4-hydroxymethyl)benzyl methacrylate) as an example, a monomer having the structure of formula (I) may be synthesized according to the following method: a diol (1.5 eq.) and triethylamine (1.5 eq.) were dissolved in dichloromethane, and after acryl chloride (1 eq.) was slowly added dropwise thereto at 0° C., they were reacted for 24 hours with stirring. After the reaction was completed, saturated brine was added, and the mixed solution was extracted with dichloromethane. The esterified monomer may be purified by means of column chromatography, recrystallization and the like.

### Example 2

410 mg of (4-hydroxymethyl)benzyl methacrylate, 900 mg of methyl methacrylate and 470 mg of benzyl acrylate were dissolved in 5 mL of tetrahydrofuran, and after 50 mg of azobisisobutyronitrile was added, they were reacted at 70° C. for 24 hours. The produced polymer was precipitated with n-hexane and dried by heating in a drying oven, to make a desired polymer.

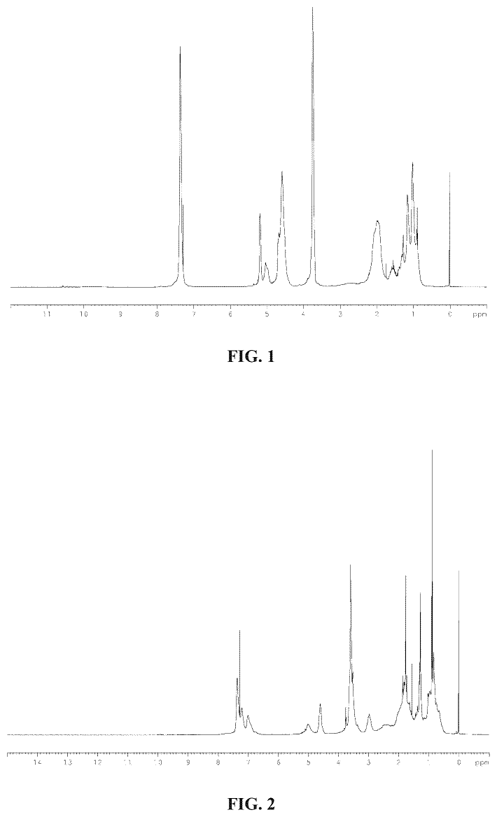

The polymer obtained in Example 2 was analyzed with nuclear magnetic resonance, to obtain its Hydrogen Nuclear Magnetic Resonance spectrogram, as shown in FIG. 1.

### Example 3

670 mg of 4-hydroxymethylstyrene, 2 g of methyl methacrylate and 500 mg of benzyl acrylate were dissolved in 10 mL of tetrahydrofuran, and after 120 mg of azobisisobutyronitrile was added thereto, they were reacted at 70° C. for 24 hours. The produced polymer was precipitated with n-hexane and dried by heating in a drying oven, to make a desired polymer.

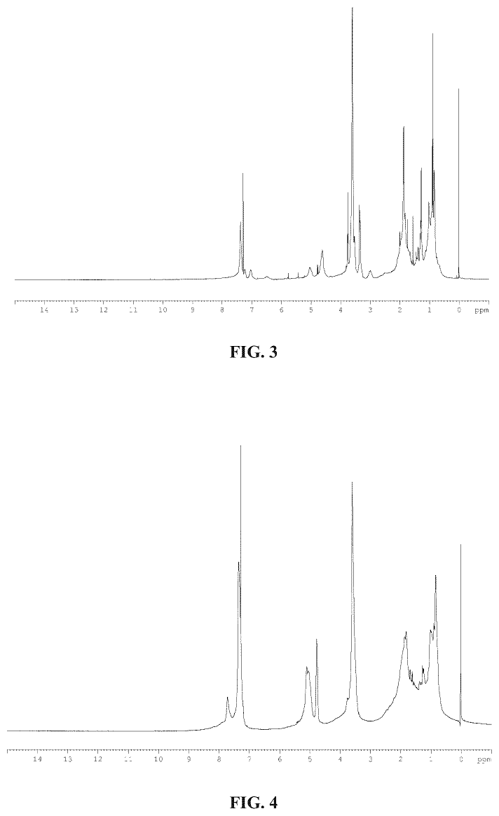

The polymer obtained in Example 3 was analyzed with nuclear magnetic resonance, to obtain its Hydrogen Nuclear Magnetic Resonance spectrogram, as shown in FIG. 2

### Example 4

200 mg of 4-hydroxymethylstyrene, 1.6 g of methyl methacrylate, 300 mg of benzyl acrylate and 510 mg of N-(methoxymethyl) methacrylamide were dissolved in 10 mL of tetrahydrofuran, and after 70 mg of azobisisobutyronitrile was added thereto, they were reacted at 70° C. for 24 hours. The produced polymer was precipitated with n-hexane and dried by heating in a drying oven, to make a desired polymer.

The polymer obtained in Example 4 was analyzed with nuclear magnetic resonance, to obtain its Hydrogen Nuclear Magnetic Resonance spectrogram, as shown in FIG. 3.

### Example 5

410 mg of (4-hydroxymethyl)pyridylmethyl methacrylate, 500 mg of methyl methacrylate and 320 mg of benzyl acrylate were dissolved in 5 mL of tetrahydrofuran, and after 50 mg of azobisisobutyronitrile was added thereto, they were reacted at 70° C. for 24 hours. The produced polymer was precipitated with n-hexane and dried by heating in a drying oven, to make a desired polymer.

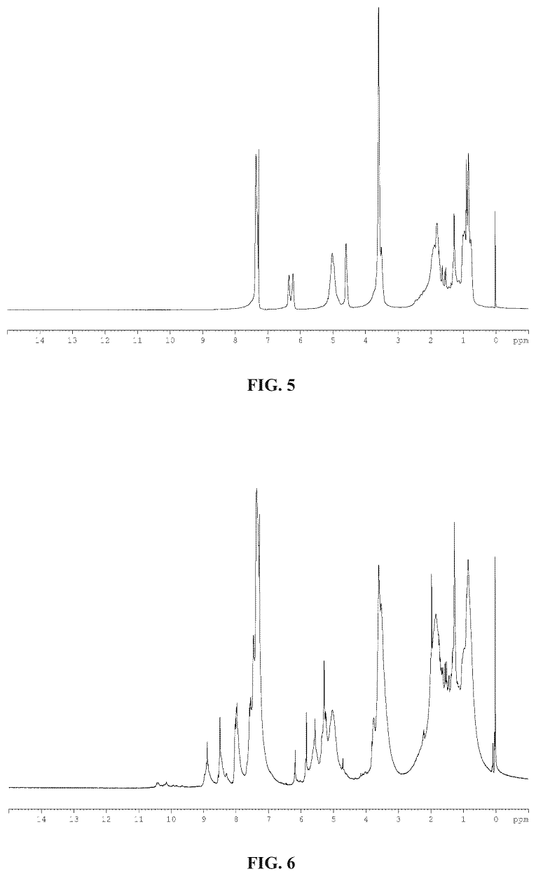

The polymer obtained in Example 5 was analyzed with nuclear magnetic resonance, to obtain its Hydrogen Nuclear Magnetic Resonance spectrogram, as shown in FIG. 4.

### Example 6

590 mg of (4-hydroxymethyl) furylmethyl methacrylate, 750 mg of methyl methacrylate and 790 mg of benzyl acrylate were dissolved in 8 mL of tetrahydrofuran, and after 74 mg of azobisisobutyronitrile was added thereto, they were reacted at 70° C. for 24 hours. The produced polymer was precipitated with n-hexane and dried by heating in a drying oven, to make a desired polymer.

The polymer obtained in Example 6 was analyzed with nuclear magnetic resonance, to obtain its Hydrogen Nuclear Magnetic Resonance spectrogram, as shown in FIG. 5.

### Example 7

140 mg of (8-hydroxymethyl) 1-anthrylmethyl methacrylate, 115 mg of methyl methacrylate and 75 mg of benzyl acrylate were dissolved in 5 mL of tetrahydrofuran, and after 11 mg of azobisisobutyronitrile was added thereto, they were reacted at 70° C. for 24 hours. The produced polymer was precipitated with n-hexane and dried by heating in a drying oven, to make a desired polymer.

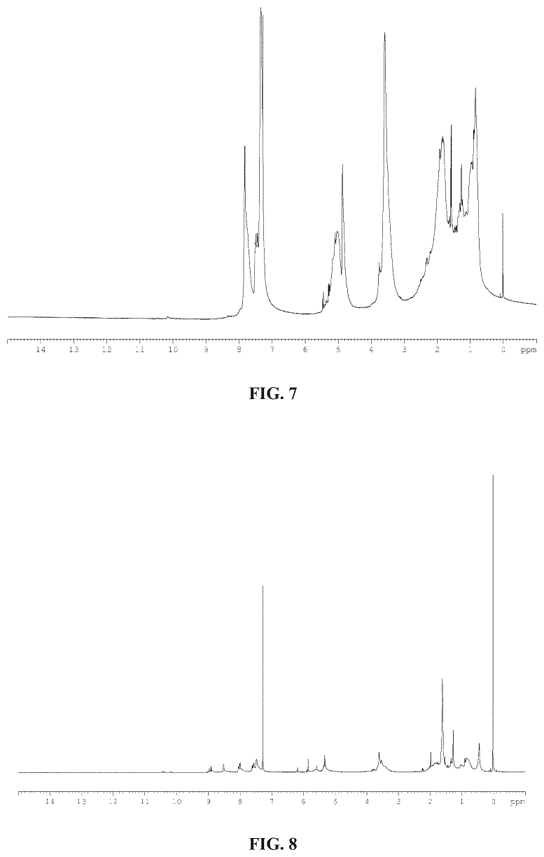

The polymer obtained in Example 7 was analyzed with nuclear magnetic resonance, to obtain its Hydrogen Nuclear Magnetic Resonance spectrogram, as shown in FIG. 6.

### Example 8

120 mg of (6-hydroxymethyl) 1-naphthylmethyl methacrylate, 98 mg of methyl methacrylate and 64 mg of benzyl acrylate were dissolved in 5 mL of tetrahydrofuran, and after 10 mg of azobisisobutyronitrile was added thereto, they were reacted at 70° C. for 24 hours. The produced polymer was precipitated with n-hexane and dried by heating in a drying oven, to make a desired polymer.

The polymer obtained in Example 8 was analyzed with nuclear magnetic resonance, to obtain its Hydrogen Nuclear Magnetic Resonance spectrogram, as shown in FIG. 7.

### Example 9

200 mg of (8-hydroxymethyl) 1-anthrylmethyl methacrylate and 82 mg of methyl methacrylate were dissolved in 5 mL of tetrahydrofuran, and after 16 mg of azobisisobutyronitrile was added thereto, they were reacted at 70° C. for 24 hours. The produced polymer was precipitated with n-hexane and dried by heating in a drying oven, to make a desired polymer.

The polymer obtained in Example 9 was analyzed with nuclear magnetic resonance, to obtain its Hydrogen Nuclear Magnetic Resonance spectrogram, as shown in FIG. 8.

### Example 10

2.3 g of methyl methacrylate and 2.6 g of N-(methoxymethyl) methacrylamide were dissolved in tetrahydrofuran, and 500 mg of azobisisobutyronitrile (AIBN) were added thereto. They were heated to reflux and reacted for 24 hours. The produced polymer was precipitated with n-hexane and dried by heating in a drying oven, to make a desired polymer

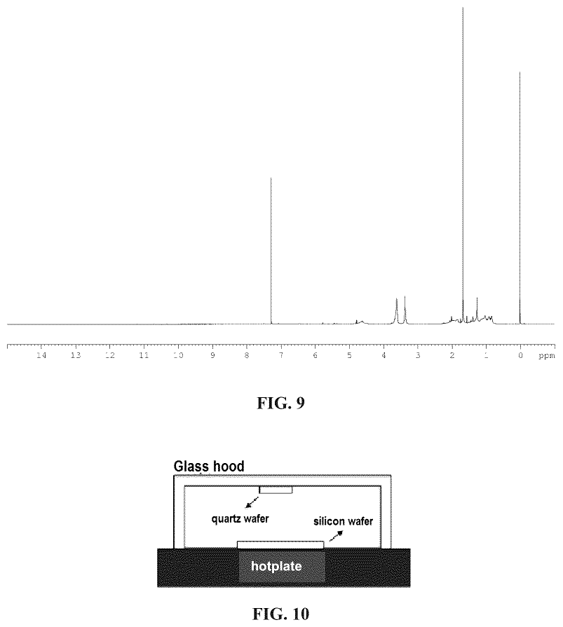

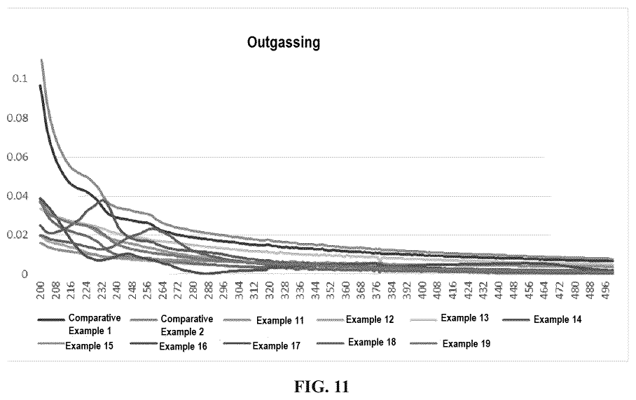

The polymer obtained in Example 10 was analyzed with nuclear magnetic resonance, to obtain its Hydrogen Nuclear Magnetic Resonance spectrogram, as shown in FIG. 9.

### Example 11

To 10 g of propylene glycol monomethyl ether containing 0.5 g of the polymer obtained in Example 2, 10 mg of toluenesulfonic acid and 100 mg of melamine were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form a 94 nm anti-reflective film.

The film was measured by a spectroscopic ellipsometer to obtain a refractive index n at 193 nm of 1.75 and an extinction coefficient k of 0.38.

### Example 12

To 10 g of propylene glycol monomethyl ether containing 0.35 g of the polymer obtained in Example 3, 10 mg of toluenesulfonic acid and 80 mg of melamine were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form a 100 nm anti-reflective film.

The film was measured by a spectroscopic ellipsometer to obtain a refractive index n at 193 nm of 1.66 and an extinction coefficient k of 0.39.

### Example 13

To 10 g of propylene glycol monomethyl ether containing 0.35 g of the polymer obtained in Example 4, 10 mg of toluenesulfonic acid were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form an 88 nm anti-reflective film.

The film was measured by a spectroscopic ellipsometer to obtain a refractive index n at 193 nm of 1.71 and an extinction coefficient k of 0.27.

### Example 14

To 10 g of propylene glycol monomethyl ether containing 0.35 g of the polymer obtained in Example 5, 10 mg of toluenesulfonic acid and 80 mg of melamine were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form a 100 nm anti-reflective film.

The film was measured by a spectroscopic ellipsometer to obtain a refractive index n at 193 nm of 1.84 and an extinction coefficient k of 0.37.

### Example 15

To 10 g of propylene glycol monomethyl ether containing 0.35 g of the polymer obtained in Example 6, 10 mg of toluenesulfonic acid and 80 mg of melamine were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form a 101 nm anti-reflective film.

The film was measured by a spectroscopic ellipsometer to obtain a refractive index n at 193 nm of 1.76 and an extinction coefficient k of 0.33.

### Example 16

To 10 g of propylene glycol monomethyl ether containing 0.3 g of the polymer obtained in Example 7, 10 mg of toluenesulfonic acid and 70 mg of melamine were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form a 78 nm anti-reflective film.

The film was measured by a spectroscopic ellipsometer to obtain a refractive index n at 248 nm of 1.64 and an extinction coefficient k of 0.36.

### Example 17

To 10 g of propylene glycol monomethyl ether containing 0.2 g of the polymer obtained in Example 8, 10 mg of toluenesulfonic acid and 60 mg of melamine were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form a 47 nm anti-reflective film.

The film was measured by a spectroscopic ellipsometer to obtain a refractive index n at 248 nm of 1.65 and an extinction coefficient k of 0.33.

### Example 18

To 10 g of propylene glycol monomethyl ether containing 0.3 g of the polymer obtained in Example 9, 10 mg of toluenesulfonic acid and 70 mg of melamine were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form an 80 nm anti-reflective film.

The film was measured by a spectroscopic ellipsometer to obtain a refractive index n at 248 nm of 1.55 and an extinction coefficient k of 0.54.

### Example 19

To 10 g of propylene glycol monomethyl ether containing 175 mg of the polymer obtained in Example 3 and 175 mg of the polymer obtained in Example 10, 10 mg of toluenesulfonic acid were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form an 82 nm anti-reflective film.

The film was measured by a spectroscopic ellipsometer to obtain a refractive index n at 193 nm of 1.68 and an extinction coefficient k of 0.26.

### Comparative Example 1

5.2 g of 1,3,5-tris(2-hydroxyethyl) cyanuric acid, 7.76 g of dimethyl terephthalate, 1.84 g of glycerol and 90 mg of p-toluenesulfonic acid were heated to 150° C. and reacted for 24 hours. The produced polymer was precipitated under t-butyl methyl ether and dried by heating in a drying oven, to make a desired polymer.

To 10 g of ethyl lactate containing 0.4 g of the above resin, 100 mg of TMGU (tetramethoxymethylglycoluril) and 10 mg of p-toluenesulfonic acid were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form a 58 nm anti-reflective film.

The film was measured by a spectroscopic ellipsometer to obtain a refractive index n at 193 nm of 1.77 and an extinction coefficient k of 0.44.

### Comparative Example 2

5.2 g of 1,3,5-tris(2-hydroxyethyl) cyanuric acid, 7.76 g of dimethyl terephthalate, 1.84 g of glycerol and 90 mg of p-toluenesulfonic acid were heated to 150° C. and reacted for 24 hours. The produced polymer was precipitated with t-butyl methyl ether and dried by heating in a drying oven, to make a desired polymer.

To 10 g of ethyl lactate containing 0.4 g of the above resin, 100 mg of TMGU (tetramethoxymethylglycoluril) and 10 mg of p-toluenesulfonic acid were added. The formulated solution was filtered through a 0.2 μm polyethylene microporous filter, to make an anti-reflective coating composition. The composition was spin coated on a silicon wafer with a spinning coater and heated with a 205° C. electric hotplate for one minute, to form a 58 nm anti-reflective film.

The film was measured by a spectroscopic ellipsometer to obtain a refractive index n at 193 nm of 1.77 and an extinction coefficient k of 0.44.

The compositions obtained in Examples 11 to 19 were coated on silicon wafers by a spin coater, and heated with a 185° C. electric hotplate for 60 seconds, to obtain the corresponding anti-reflective films that were measured with their film thicknesses. The films were immersed in a photoresist solvent such as ethyl lactate, propylene glycol monomethyl ether, and the like, for 20 seconds. The films were baked at 100° C. for 30 seconds and then their film thicknesses were measured again. For Examples 11 to 19, the difference between the two former and latter film thickness measurements was less than 1 nm, confirming that the anti-reflective films were insoluble in the solvents used for the photoresist.

Comparative Example 1 and Comparative Example 2 were tested according to the above method, and it was found that the former and latter film thicknesses in Comparative Example 1 significantly varied, demonstrating that after the film was baked, it can still be dissolved in the solvents of the photoresist, while the difference between the former and latter film thickness in Comparative Example 2 were less than 1 nm, conforming that the film was insoluble in the solvents of the photoresist. This shows that the baking temperature of Comparative Example 1 is insufficient to enable the crosslinking reaction to sufficiently occur, while the baking temperature of Comparative Example 2 enables the crosslinking reaction to sufficiently occur.

The specific data was shown in Table 1, and it can be determined that the examples enable the crosslinking reaction to sufficiently occur at a relatively low temperature.

TABLE 1
Measured results of film thickness of anti-reflective films
before and after immersion in solvents of photoresists

| | Baking | Film thickness |
|---|---|---|
| | temperatures | difference (nm) |
| Example 11 | 185° C. | <1 |
| Example 12 | 185° C. | <1 |
| Example 13 | 185° C. | <1 |
| Example 14 | 185° C. | <1 |
| Example 15 | 185° C. | <1 |
| Example 16 | 185° C. | <1 |
| Example 17 | 185° C. | <1 |
| Example 18 | 185° C. | <1 |
| Example 19 | 185° C. | <1 |
| Comparative Example 1 | 185° C. | Wash off |
| Comparative Example 2 | 205° C. | <1 |

To 10 g of propylene glycol monomethyl ether containing 175 mg of the polymer obtained in Example 3 and 175 mg of the polymer obtained in Example 10, 10 mg of toluenesulfonic acid were added. The formulated solution was filtered through a 0.2 μm polyethylene microporous filter, to make an anti-reflective coating composition. The composition was spin coated on a silicon wafer with a spinning coater and heated with a 185° C. electric hotplate for one minute, to form an 82 nm anti-reflective film.

Dry etching rate measurements were performed according to the following method. The solutions obtained from Examples 11-15 of ArF were spin coated on silicon wafers, respectively, and cured into a film by heating and baking with an electric hotplate at the corresponding temperatures. The obtained films were tested for the etching rate of O₂ gas using an inductively coupled plasma etcher HAASRODE-E200A and the results are summarized as shown in Table 2. From the results, it can be seen that Example 11 and Examples 14-15 have faster etching rates compared to Examples 12-13, which is beneficial for accurate and rapid reproduction and transfer of patterns.

TABLE 2

| Examples | Relative etching rate |
|---|---|
| Example 11 | 1.51 |
| Example 12 | 1.10 |
| Example 13 | 1.00 |
| Example 14 | 1.48 |
| Example 15 | 1.65 |

The sample formulated according to the examples was coated onto a silicon wafer to determine the refractive index and extinction coefficient (n&k) of the anti-reflective coating. Further, with the measured data as parameters, a proflith software was used to calculate the reflective coefficient of the photoresist-stacked anti-reflective coating at 193 nm and determine the optimal thickness of the anti-reflective coating with a minimal reflective coefficient, and the results were shown in Table 3.

TABLE 3
Measured results of reflective indexes of anti-reflective coatings

| | | | Optimal film thicknesses with |
|---|---|---|---|
| Examples | n | k | minimal reflective index |
| 14 | 1.84 | 0.37 | 85 |
| 15 | 1.76 | 0.33 | 93 |

The above contents are only concerned to the preferred embodiments of the present disclosures. It should be indicated that the above preferred embodiments should not be considered to limit the present invention, and the protection scope of the present disclosure should be based on the scope as defined in the claims. For a person skilled in the art, without deviating from the spirit and scope of the present disclosures, several improvements and modifications may be made, and these improvements and modifications should be also considered in the protection scope of the present disclosure.

What is claimed is:

1. An anti-reflective coating composition comprising:
an organic polymer, wherein the organic polymer comprises a crosslinkable polymer; and
the crosslinkable polymer comprises a monomer unit formed by a monomer represented by formula (I): 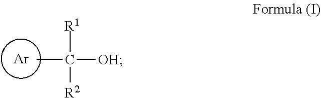
wherein 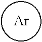
is selected from substituted C₆-C₂₀ aryl or substituted C₃-C₂₀ heteroaryl;
the substituents in the substituted C₆-C₂₀ aryl and substituted C₃-C₂₀ heteroaryl include unsaturated bonds; and
the R¹ and R² are each independently selected from a group consisting of H, substituted or unsubstituted C₁-C₆ alkyl, and substituted or unsubstituted C₆-C₂₀ aryl.

2. The anti-reflective coating composition according to claim 1, wherein substituents in the substituted C₆-C₂₀ aryl and substituted C₃-C₂₀ heteroaryl are selected from a group consisting of substituted or unsubstituted C₄-C₁₅ alkenoic alkyl ester group, and substituted or unsubstituted C₂-C₁₀ alkenyl;
the substituents in the substituted or unsubstituted C₄-C₁₅ alkenoic alkyl ester group and substituted or unsubstituted C₂-C₁₀ alkenyl are each independently one or more selected from a group consisting of C₁-C₅ alkyl, C₁-C₆ alkoxy and phenyl; and
the substituents in the substituted C₁-C₆ alkyl and substituted C₆-C₂₀ aryl are each independently one or more selected from a group consisting of C₁-C₅ alkyl, C₁-C₆ alkoxy and phenyl.

3. The anti-reflective coating composition according to claim 1, wherein the 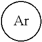
is selected from substituted phenyl, substituted naphthyl, substituted anthracyl, substituted pyridyl or substituted furyl.

4. The anti-reflective coating composition according to claim 1, wherein the monomer represented by formula (I) is one or more selected from a group consisting of (4-hydroxymethyl)benzyl methacrylate, 4-hydroxymethyl styrene, (4-hydroxymethyl)pyridylmethyl methacrylate, (4-hydroxymethyl) furylmethyl methacrylate, (8-hydroxymethyl) 1-anthrylmethyl methacrylate and (6-hydroxymethyl) 1-naphthylmethyl methacrylate.

5. The anti-reflective coating composition according to claim 1, wherein the amount of the monomer unit formed by the monomer represented by formula (I) in the crosslinkable polymer is 5 wt %-60 wt %; the mass of the crosslinkable polymer is 10%-100% of the mass of the organic polymer; and the mass of the organic polymer is 2%-10% of the mass of the anti-reflective coating composition.

6. The anti-reflective coating composition according to claim 1, wherein the crosslinkable polymer further comprises a light-absorbing organic chromophore and/or the organic polymer further comprises a first polymer; the first polymer comprises a light-absorbing organic chromophore; the light-absorbing organic chromophore is one or more selected from a group consisting of substituted or unsubstituted aryl, polyhaloalkyl, and a substituted or unsubstituted isocyanuric acid ester group.

7. The anti-reflective coating composition according to claim 6, wherein the mass of the monomer unit comprising the light-absorbing organic chromophore is 10%-85% of the mass of the organic polymer.

8. The anti-reflective coating composition according to claim 1, wherein the anti-reflective coating composition further comprises a crosslinking agent; the crosslinking agent is one or more selected from a group consisting of a melamine crosslinking agent, a urea crosslinking agent, and an epoxy group-containing polymeric crosslinking agent; and the mass of the crosslinking agent is 0.1%-20% of the mass of the anti-reflective coating composition.

9. The anti-reflective coating composition according to claim 8 comprising the melamine crosslinking agent, wherein the melamine crosslinking agent is one or more selected from a group consisting of methoxymethylated melamine, melamine, benzoguanamine and corresponding resins the methoxymethylated melamine, the melamine, and the benzoguanamine.

10. The anti-reflective coating composition according to claim 8 comprising the urea crosslinking agent, wherein the urea crosslinking agent is one or more selected from a group consisting of methoxymethylated glycoluril, tetramethoxymethyl urea and tetrabutoxy methyl urea.

11. The anti-reflective coating composition according to claim 1, wherein the anti-reflective coating composition further comprises a thermal acid generator, a photoacid generator, a surfactant and a solvent; the mass of the thermal acid generator is 0.1%-15% of the mass of the anti-reflective coating composition; the mass of the photoacid generator is 0%-15% of the mass of the anti-reflective coating composition; the mass of the surfactant is 0%-20% of the mass of the anti-reflective coating composition; and the mass of the solvent is 90%-99% of the mass of the anti-reflective coating composition.

12. A method for forming a pattern image with photoresist during manufacturing semiconductor device, wherein it comprises a film-forming step of the anti-reflective coating composition according to claim 1, a film-forming step of photoresist, and a subsequent irradiation-exposing step followed by the developing step of photoresist.
